(19) United States
(12) Patent Application Publication
(10) Pub. No.: US 2025/0068054 A1
(43) Pub. Date: Feb. 27, 2025

(54) Mask and Reticle Protection with Atomic Layer Deposition (ALD)

(71) Applicant: Nano-Master, Inc., Austin, TX (US)

(72) Inventor: Birol Kuyel, Austin, TX (US)

(21) Appl. No.: 18/945,949

(22) Filed: Nov. 13, 2024

Related U.S. Application Data
(63) Continuation of application No. 17/130,503, filed on Dec. 22, 2020, now Pat. No. 12,197,125.

(51) Int. Cl. G03F 1/48; G03F 1/24; G03F 1/26; G03F 1/62; G03F 7/00; H01L 21/033

(52) U.S. Cl. CPC G03F 1/48; G03F 1/24; G03F 1/26; G03F 1/62; G03F 7/70983; H01L 21/0332; H01L 21/0337

(57) ABSTRACT

Techniques are disclosed for protecting a lithographic mask and its lithographic pattern during the lifecycle of the mask. This is accomplished by deposited an extremely uniform and geometrically conformal protective coating on the mask that provides it mechanical and electrostatic protection. The coating is doped by introducing a controlled amount of hydrogen in it. The coating envelopes or surrounds the pattern on the mask thereby providing it protection during the various operations in the lifecycle of the mask, including cleanings, repairs, inspections, etc. The conformal coating is deposited in a hybrid reactor by a plasma-enhanced ALD (PEALD) or preferably still a continuous-flow PEALD, and is then carefully doped with a controlled amount of hydrogen.

### CROSS-REFERENCE TO RELATED APPLICATIONS

This application is a continuation-in-part of now allowed U.S. patent application Ser. No. 17/130,503 filed on Dec. 22, 2020, which is incorporated by reference for all purposes in its entirety.

This application is also related to U.S. patent application Ser. No. 16/738,240 issued as U.S. Pat. No. 11,087,959 B2 on Aug. 10, 2021, U.S. patent application Ser. No. 15/458,642 issued as U.S. Pat. No. 9,972,501 B1 on May 15, 2018, U.S. patent application Ser. No. 15/950,330 issued as U.S. Pat. No. 10,366,898 B2 on Jul. 30, 2019, U.S. patent application Ser. No. 15/950,391 issued as U.S. Pat. No. 10,361,088 B2 on Jul. 23, 2019 and U.S. Patent Application No. 488,315 issued as U.S. Pat. No. 4,537,813 on Aug. 27, 1985. All the above-numbered patent applications and patents are incorporated by reference for all purposes in their entireties.

### FIELD OF THE INVENTION

This invention relates generally to lithography and more specifically for protecting lithography/lithographic masks/reticles with their lithography/lithographic patterns used in printing of integrated circuits.

### BACKGROUND ART

Patterned lithographic masks or lithography masks are used in lithography for printing electronic circuits on silicon wafers. There are many different types of masks used in the industry. Photomasks are used for 1:1 contact printing or proximity printing. Alternately, they are used for 5:1 or 4:1 projection printing. From the perspective of principles of operation, a lithographic photomask may be a binary photomask or a phase-shift photomask (PSM) for higher resolutions. The mask may also be an extreme ultraviolet (EUV) mask.

A lithography mask has a high-resolution pattern that absorbs electromagnetic radiation incident on the mask. For a photomask, the pattern is deposited on a glass substrate and absorbs optical light. For an EUV mask, the pattern is deposited on a reflective multilayer (ML), typically of silicon (Si) and Molybdenum (Mo). The feature sizes of the pattern are ever-shrinking.

The quality of the pattern is very critical to the semiconductor manufacturing process, and the lithography masks must therefore be produced free from any defects. Maintaining the masks in this defect-free state is essential if high device yields are to be maintained. In addition to particulate contamination, the various cleaning, inspection and handling operations that the mask must undergo can cause a slow deterioration of the pattern.

Additionally, the pattern, typically made out of metal, is an electrical conductor, whereas the underlying substrate is an insulator. As a result of various processes, such as by electrostatics or ultraviolet (UV) illumination-emission of photoelectrons, islands of metallic pattern can undesirably be charged to different electrical potentials. If a potential difference of a few volts occurs over a short distance of a micron, an electrical discharge can occur. This discharge ablates material from the metallic pattern causing its erosion and/or formation of pinholes in it and causing particles to land on the mask thereby producing defects. When such defects are multiplied by the numerous masks required to fabricate a given semiconductor device, the yield loss can become significant. If the same mask prints hundreds of chips on the same wafer, then all the chips may be dead, and if the same mask is used for all the wafers then one killer defect can bring total good chip yield to zero.

One approach to protecting a metallic photomask pattern as described in U.S. Pat. No. 3,906,133 to Flutie is to deposit a simple protective coating thereon. That patent describes an iron oxide masking layer on a transparent substrate which has a protective nitrocellulose coating thereon. The coating has a thickness greater than the height of protrusions on the surface. However, these techniques are directed only towards contact printing wherein the photomask is placed in intimate contact with the photoresist coated wafer.

But, in projection printing, the photomask is spaced from the resist coated wafer and the light passing through the photomask must be focused onto the resist coating by an optical system. It has been observed that such protective coatings do not have uniform thickness and cause reflection of the light due to the difference between the refractive indices of the substrate and the coating material, resulting in poor pattern definition. Additionally, nitrocellulose film coating has other disadvantages. Being made of plastic, it can be easily scratched and being a good dielectric, its surface can readily charge.

If the mask/reticle is not un-pelliclized, the substantial charge on a typical underlying quartz substrate attracts particles that rain upon the mask. Furthermore, the surface charge also electrostatically attracts particles raising the number of defects. Even though “clean rooms” used for very large-scale integration (VLSI) minimize the number of such defect causing particles, the masks may still need be cleaned to remove those particles, resulting in a loss of yield. As feature sizes shrink, smaller and smaller particles not only can be accumulated much faster with charged surfaces, but they are also much more difficult to remove with known cleaning techniques. The combination of more frequent cleaning, susceptibility of surface scratches during cleaning, and accumulation of unremovable defects results in frequent removal and reapplication of such film, causing further defects in the mask pattern.

For addressing the needs of an inexpensive design for protecting the metallized surface of a mask while maintaining high definition and low defect densities, an alternative technique was proposed in U.S. Pat. No. 4,537,813 to Birol. This patent is incorporated by reference herein for all purposes in its entirety. In this patent, plasma deposited silicon dioxide (SiO2) is used as a protective layer over metallic patterns in order to prevent electrostatic damage and wear during cleaning. Deposited film has substantially matching index to that of underlying substrate, such as glass.

The above results in good step coverage around the metallic pattern and further bulk conductivity to eliminate charging non-uniformity or voltage differential between islands of the metal. In addition, a surprising additional benefit is observed: the printed pattens have higher resolution because thickness of the coating at the edge of Cr patterns acts as a phase-shift enhancement. However, a drawback of the above design is that small crystalline particles in the SiO2 film cannot be fully eliminated. Their diffraction patterns are thus printed as defects. As feature sizes of today's design rules shrink, the step coverage of the deposited SiO2 film is not satisfactory, even when deposition is performed using plasma enhanced chemical vapor deposition (PECVD).

Atomic layer deposition (ALD) is a type of vacuum deposition technique. ALD utilizes a sequential exposure of gaseous reactants for the deposition of atomically sized thin films. The reactants are often metal precursors consisting of organometallic liquids or solids used in the chemistry by vaporizing under vacuum and/or heat conditions. The reactants are introduced as a series of sequential, non-overlapping pulses. In each of these pulses, the reactant molecules react with a substrate or wafer surface in a nucleation-based and self-limiting way.

Consequently, the reaction ceases once all the sites on the wafer/substrate surface are consumed. Between the pulses, a purge step is applied to remove the excess reactants and byproducts from the process chamber. Using ALD, it is possible to grow materials uniformly and with high-precision on arbitrarily complex and large substrates. Some examples of films produced using ALD are SiO2, Si3N4, Ga2O3, GaN, Al203, AlN, etc.

There is prior art utilizing ALD for forming a protective coating in photomasks. U.S. Patent Publication No. 2016/0342079 A1 to Oh et al. discloses a photomask that includes a transparent substrate, a mask pattern formed on the substrate, and a coating covering sidewalls of the mask pattern. The coating may be formed using ALD. The objective of their design is to make a phase-shift photomask (PSM) and not to protect the underlying mask pattern. Therefore, as a shortcoming of their technology, the coating on top of the masked pattern is removed in order to make the PSM. Their design cannot protect the lithographic pattern.

It is therefore desirable to protect a lithography/lithographic mask or reticle and its lithography/lithographic pattern by a protective coating. It is also desirable for the coating to be nucleation-based and conformal to the mask/reticle and be extremely uniform over the entire mask/reticle. The mask/reticle may be a photomask/photo-reticle or an EUV mask/reticle. Such a design would achieve the advantages of electrostatic charge uniformity over the pattern while at the same time eliminating small crystalline particles that are otherwise inevitably attracted to it in the techniques of the prior art. Techniques are also absent from the prior art about doping such a coating with hydrogen in a controlled manner.

### OBJECTS OF THE INVENTION

In view of the shortcomings of the prior art, it is an object of the present technology to provide methods and apparatus/systems for depositing a protective conformal coating or film using ALD over a lithographic pattern of a lithography mask/reticle. The lithographic pattern absorbs electromagnetic radiation incident on the mask/reticle.

It is also an object of the present technology to deposit such a protective conformal coating on a mask that may be a photomask or an extreme ultraviolet (EUV) mask. In the case of an EUV mask, EUV electromagnetic radiation or illumination is transmitted through an instant thin coating before being reflected by the mask.

It is another object of the instant design to produce such a protective conformal coating one atomic layer at a time using ALD. The ALD may be plasma-enhanced ALD (PEALD).

It is another object of the present design to deposit the conformal coating using continuous-flow PEALD.

It is another object of the current invention to form such a protective conformal coating by nucleation-based reactions.

It is still another object of the invention to deposit such a protective coating over a reticle that is pelliclized afterwards.

It is another object of the present technology to achieve excellent step coverage of its protective conformal coating deposited over the lithographic pattern.

While performing continuous-flow PEALD, it is an object of the invention to produce a high quality/uniformity conformal coating/film with fast cycle-times and low cost of operation.

It is also an object of the invention to dope such a conformal coating with hydrogen in a controlled manner.

Still other objects and advantages of the invention will become apparent upon reading the detailed description in conjunction with the drawing figures.

### SUMMARY

The objects and advantages of the present technology are secured by methods and apparatus/systems for depositing a conformal coating or film on a lithographic mask or a reticle. The conformal coating is meant to protect the electromagnetic radiation absorbing pattern on the mask that is used for printing integrated circuits on wafers. The objective of the coating is to protect the pattern while the protected lithographic mask undergoes various lithographic operations during its lifecycle including cleanings, repairs, inspections, etc.

The protective coating is deposited using the techniques of atomic layer deposition (ALD). The coating thus deposited is therefore produced by nucleation-based chemical processes, as opposed to chemical vapor deposition (CVD) based processes of the prior art. The coating is deposited conformally on all sides or sidewalls as well as on the top/tops or distal end/ends of the pattern on the lithographic mask.

The conformal coating thus deposited is retained on all sides as well as the top(s) of the pattern to render it protection during the lifecycle of the mask. In contrast to the present technology, the techniques of the prior art remove the conformal coating from the top(s) in order to produce phase-shift masks. Since the present design is aimed at protecting the pattern on the substrate completely, the conformal ALD coating is retained around all edges/peripheries of the pattern, as opposed to just the sides as in prevailing technologies.

In various embodiments, the lithographic mask protected by instant conformal coating may be a binary photomask, a phase-shift photomask (PSM), a projection photomask, a contact photomask, a proximity photomask, an extreme ultraviolet (EUV) mask or the like. In related variations, the instant conformal coating may be used to protect a reticle of any of the above masks rather than the entire mask. In still other variations, the reticle may be housed in or protected by a pellicle after the depositing of the instant conformal coating.

In a preferred embodiment, the conformal coating is composed of an oxide. Preferably, the oxide coating is actually silicon dioxide (SiO2) that acts as a “leaky dielectric”. The “leakiness” of the dielectric is facilitated by doping the conformal coating with a suitable doping agent/specie or dopant. Preferably still, the conformal protective coating is composed of more than one type of materials or chemical species, such as a combination of more than one oxides.

In another embodiment, the substrate underlying the metallic pattern of the mask is a glass substrate. The glass substrate may actually be composed of fused silica or quartz or a soda-lime or the like. The present techniques allow for the conformal coating to take place at much less extreme temperatures than the techniques of the prior art. More specifically, the instant coating can take place at a substantially room temperature, or at least in the range of 20-60° C.

In other embodiments, the refractive indices of the conformal coating and substrate materials are kept substantially similar. More specifically, the difference in indices is kept less than or equal to 1/100. This allows for avoidance of reflection and interference patterns at the coating/substrate interface resulting in less optical defects and ultimately greater yield.

In embodiments where the lithographic mask being protected by the instant conformal coating is an EUV mask, the refractive index of the coating may be matched to the index of the capping layer or the index of the topmost layer of the multilayer (ML) of the EUV mask. This allows for ease of optical inspections of the EUV mask under actinic wavelengths.

In a set of highly preferred embodiments, the ALD process employed for depositing the instant conformal coating is a plasma-enhanced ALD (PEALD) or a plasma-assisted or plasma-activated ALD (PAALD). The nucleation-based processes occurring in such a PEALD-based or PAALD-based design allow for the instant conformal coating to deposit one atomic layer at a time, and henceforth with extremely uniform thickness. In a set of related highly preferred embodiments, the PEALD or PAALD used is a continuous-flow PEALD or PAALD.

The instant coating resulting in the above-described embodiments have a number key benefits or advantages over the prior art. These include having an extremely uniform electrostatic potential across the coating by appropriate doping of the coating/film. Henceforth, this avoids forming of islands of electrostatic potential that may otherwise result in arching and consequent damaging of the pattern, as in the techniques of the prior art. Thus, instant protective conformal coating protects the underlying pattern not only from mechanical damage but also electrostatic/static arching. Differently put, instant protective conformal coating provides mechanical as well as electrostatic protection to the lithographic pattern. In the case of an EUV mask, it protects the mask from collecting particles with electrostatic charge and from mechanical damage during handling or cleaning.

Other advantages include uniform stochiometric composition and consequently uniform index of refraction, and excellent step coverage. The benefits also include no optical defects due to crystalline particles as in the prior art, because the chemical process generating the coating is nucleation-based per above. The benefits of the instant design further include the ability to grow a gradient based coating such as using different chemical species for matching various materials underneath. Furthermore, since the coating is ultra-smooth, there is reduced scattering of incident electromagnetic radiation.

In a set of highly preferred embodiments, hydrogen is used as the doping specie or as the dopant in the instant conformal coating. The amount hydrogen doped is carefully controlled by a number of modifications to the design and workings of the prior embodiments. These embodiments utilize the hybrid reactor design disclosed and taught in the incorporated by reference U.S. Pat. No. 11,087,959. More specifically, after each phase of the deposition of instant conformal coating by PEALD, the plasma source and the precursors are switched off. Now, the doping phase commences in which hydrogen is introduced into the chamber and an RF potential is provided to the metal plate of the hybrid reactor. This results in the formation of hydrogen plasma around the coating deposited in the prior PEALD phase.

Simultaneously, pulsed DC voltage in the form of alternating positive and negative voltage pulses is supplied to the platen. The positive pulses neutralize the electrons from the plasma around the platen on which the lithography mask covered by the instant conformal coating rests. Negative pulses result in H+ ions from the plasma being attracted and bombarded/sprayed onto the coating. After each PEALD phase the resistivity of the coating is measured to determine if it has reached a desired value. Otherwise, doping phase is performed. The above apparatus and methods allow a practitioner to accurately control the amount of hydrogen doped into the coating. The PEALD and doping phases are repeated as many times as needed to achieve the desired thickness and resistivity levels of the conformal coating.

Hydrogen as a dopant renders the instant coating a number of desirable properties. These include much better electrostatic charge protection than various other doping species. These also include a much higher/better elimination of voids and crystalline particles from the coating as compared to other dopants. The crystalline particles would otherwise cause optical defects in the coating, thereby reducing the efficacy of the mask and consequently reducing the manufacturing yield. Other relevant teachings of the prior embodiments apply to the present embodiment using hydrogen as the dopant also.

Clearly, the system and methods of the invention find many advantageous embodiments. The details of the invention, including its preferred embodiments, are presented in the below detailed description with reference to the appended drawing figures.

### BRIEF DESCRIPTION OF THE DRAWING FIGURES

FIG. 1 illustrates a cross-sectional view of a lithography mask on which an instant protective conformal coating/film is deposited.

FIG. 2 shows a cross-sectional view of a portion of a protected instant lithography mask, explicitly showing individual atomic layers of an instant conformal coating.

FIG. 3 illustrates a cross-sectional view of a continuous-flow plasma-enhanced atomic layer deposition (PEALD) chamber assembly of a preferred embodiment that is used to deposit an instant conformal coating.

FIG. 4 shows a cross-sectional view of an embodiment where a pellicle is used to cover/house a protected lithographic mask or reticle containing an instant conformal coating protecting the mask with its lithographic pattern on an underlying substrate.

FIG. 5A shows an embodiment where an instant conformal coating is used to protect an extreme ultraviolet (EUV) lithographic mask or a reticle with its lithographic pattern composed of an absorber material.

FIG. 5B shows the embodiment of FIG. 5A where a pellicle is used to house/cover the EUV mask/reticle.

FIG. 6 shows a dataset from an exemplary embodiment depositing an instant conformal coating of SiO2 at 200° C. on a lithography mask, using continuous-flow PEALD.

FIG. 7 is a variation of the embodiment of FIG. 6 performing the deposition at 80° C.

FIG. 8 is a variation of the embodiment of FIG. 6 performing the deposition at room temperature.

FIG. 9A shows a PEALD chamber or reactor that is especially suited for depositing an instant conformal coating with hydrogen as the doping agent.

FIG. 9B shows a lithography mask 143H with four lithographic patterns and an ALD plate with a recess in which the mask is placed.

FIG. 9C shows the mask of FIG. 9B seated into the recess of the ALD plate.

FIG. 10 shows an RF switch configuration that is used to provide switching in the present embodiments.

FIG. 11 shows the timing diagram for the operation of an instant reactor in which H2 is used as a dopant.

FIG. 12 shows a curve with respect to time of the potential difference/voltage of H2 plasma and the potential difference/voltage of the surface of an instant coating for the embodiments of FIG. 10-11.

### DETAILED DESCRIPTION

The figures and the following description relate to preferred embodiments of the present invention by way of illustration only. It should be noted that from the following discussion, alternative embodiments of the structures and methods disclosed herein will be readily recognized as viable alternatives that may be employed without departing from the principles of the claimed invention.

Reference will now be made in detail to several embodiments of the present invention(s), examples of which are illustrated in the accompanying figures. It is noted that wherever practicable, similar or like reference numbers may be used in the figures and may indicate similar or like functionality. The figures depict embodiments of the present invention for purposes of illustration only. One skilled in the art will readily recognize from the following description that alternative embodiments of the structures and methods illustrated herein may be employed without departing from the principles of the invention described herein.

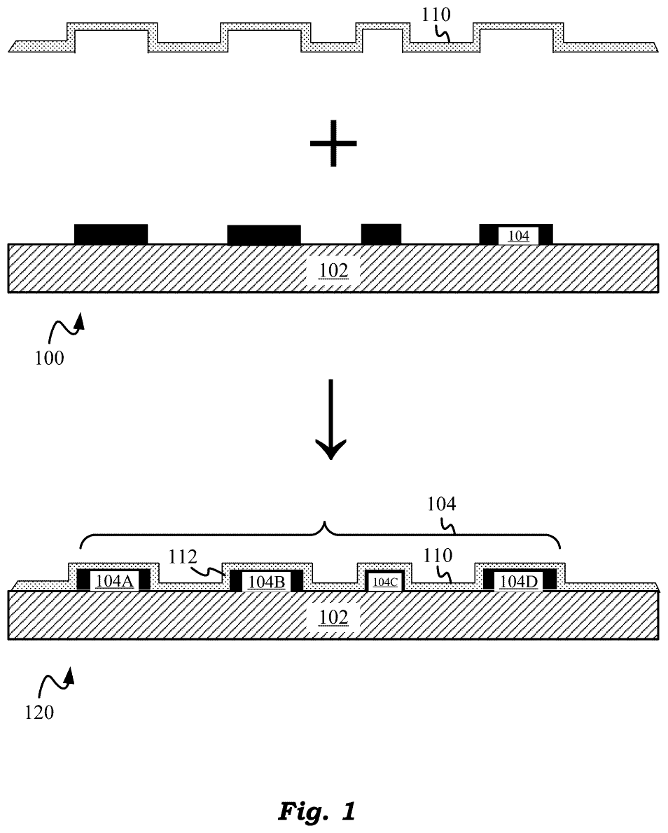

The present technology will be best understood by first reviewing a lithography mask on which an instant conformal protective coating is deposited as shown in FIG. 1. In the embodiment of FIG. 1, a cross-sectional view of a typical lithography mask 100 is shown with a substrate 102 on which a pattern 104 has been deposited or grown. As appreciated by those skilled in the art, when electromagnetic radiation 10 is incident upon mask 100 from above, pattern 104 absorbs this radiation. The radiation that is not absorbed by pattern 104 is allowed to go through transparent substrate 102 if mask 100 is a photomask, and reflected back if mask 100 is an extreme ultraviolet (EUV) mask, and then onto a silicon wafer that is consequently etched with the desired integrated circuit.

FIG. 1 further shows an instant conformal coating 110 based on the instant principles. Coating 110 is deposited conformally on pattern 104 of mask 100, thereby resulting in a protected lithography mask 120 as shown. Protected lithography mask 120 has many desirable properties as compared to the traditional lithography mask 100 as will be taught herein. Note that protected lithography mask 120 in the lower portion of FIG. 1 explicitly identifies four distinct features 104A, 104B, 104C and 104D of pattern 104 shown by the bracket. Conformal coating protects features 104A-D of pattern 104 during the lifecycle of protected mask 120. Of course, conformal coating 110 also protects the areas of substrate 102 exposed or not covered by pattern 104. These are the portions of substrate 102 shown in FIG. 1 where features 104A-D do not exist.

Features 104A-D may be of the same height although that is not a requirement for protective conformal coating of the present design to protect pattern 104 and accrue its benefits. Explained further, the tops or the distal ends of features 104A-D may not be in the same plane, and further the features may not even be connected to one another, and/or may not have top surfaces that are even. The present technology admits of any number, sizes and shapes of such features 104A, 104B, . . . , connected or isolated, of electromagnetic radiation absorbing pattern 104 of protected lithography mask 120. Therefore, pattern 104 may have many tops or distal ends and of course many sidewalls or simply sides.

By a conformal coating we mean that the coating is deposited on the pattern features regardless of their number and sizes and while conforming to their exterior shapes, regardless of the form of the shapes. In other words, it completely surrounds or envelopes all features of the pattern in a geometrically conformal manner. Of course, there is one side of the features that is attached to the underlying mask/substrate on which the coating is not deposited.

With the above in mind, in order to avoid unnecessary repetition and to avoid detraction from the key principles, the teachings and drawing figures of this disclosure may reference lithographic patterns, such as pattern 104 of FIG. 1, only in the singular. In other words, a lithography pattern or lithographic pattern may be referenced with a single top or distal end with the implicit knowledge that it actually likely has many individual tops or apexes or summits corresponding to its individual features. Of course, a lithography pattern will always be considered as having more than one or multiple sides or sidewalls because even a single feature, such as feature 104A of pattern 104 will have more than one sides/sidewalls.

Conformal protective coating or protective conformal coating or simply conformal coating 110 of FIG. 1 is exemplarily made of an oxide such as silicon dioxide (SiO2). But the present technology admits of any suitable material for coating 110. Conformal coating 110 provides a mechanical barrier over underlying pattern 104 and protects it from mechanical damage during use/operation, inspections and cleaning operation(s) of mask 120. Pattern 104 may be composed of a suitable metal such chromium (Cr) with an overlying chromium oxide layer, or pattern 104 may be composed of any other suitable material, such as tantalum (Ta), tungsten (W), etc. Underlying substrate may be a glass substrate composed of fused silica, quartz, soda-lime, etc.

It is critical that such a protective coating not introduce image distortions and degradation. In the techniques of the prior art, such as U.S. Pat. No. 4,537,813 to Birol referenced above in the Background section and incorporated by reference herein, it was shown that actually such a coating may improve local image resolution in photolithography. However, since the protective coating was deposited via chemical vapor deposition (CVD) or plasma enhanced CVD (PECVD), it was inherently prone to physical and chemical imperfections. The present technology overcomes these shortcomings of the prior art by growing protective coating 110 of FIG. 1 conformally using ALD/PEALD one atomic layer at a time.

Before proceeding further, it will be appreciated by the skilled reader that lithography is a process for microfabricating a wafer. Photolithography uses light to transfer a geometric pattern via optical refraction from a photomask (also referred to as an optical mask) to a light-sensitive or photosensitive chemical photoresist layer on the wafer. On the other hand, in extreme ultraviolet (EUV) lithography, an EUV mask is used for transferring the mask pattern onto the wafer via reflection.

Furthermore, in projection photolithography, the photomask does not stay in direct contact with the wafer, or in other words, the photomask stays above the wafer. Such a photolithography typically employs demagnification of the pattern in a 1:4 or 1:5 ratio while transferring it onto the wafer. On the other hand, in contact lithography, also known as contact printing, pattern image is printed onto the wafer via shadow-graphy in a 1:1 ratio by illumination of a contact photomask in direct contact with the photoresist on the wafer.

In order to overcome some of the limitations of contact photolithography, in a related technique known as proximity photolithography, the mask is kept ever so slightly above the wafer. As a consequence of the differences in their operating principles, projection photolithography can only capture a limited spatial frequency spectrum from photomask, whereas contact printing has no such resolution limit. However, it is more sensitive to the presence of defects and/or resist residue on the photomask or on the wafer.

In the case of a projection photomask, a typical setup involves a reticle that undergoes a step-and-repeat operation. An EUV mask also uses a reticle that has a pattern to print a subset of a single layer of the wafer. In either case, in order to expose the entire wafer a reticle has to be stepped and repeated. On the other hand, a contact photomask provides a 1:1 exposure to the underlying wafer without such a step-and-repeat operation.

Thus, depending on the type of technology, a mask may contain a pattern that can be printed in a single exposure to cover the entire wafer in a 1:1 manner, whereas a reticle only refers to a subset of the mask pattern for a single layer or section of the wafer. Most typically, an EUV setup uses a reticle exposing only a section of the wafer via electromagnetic reflection. A set of steps are then typically required to expose the entire wafer in what is referred to as a step-and-scan technology. Unless otherwise explicitly distinguished, the relevant benefits of the present technology discussed in this disclosure apply to both a lithography/lithographic mask or a (lithography/lithographic) reticle.

Furthermore, a photomask may be a binary photomask in which a photomask blank is covered with patterned layer of opaque material. Its transmission properties are binary, i.e. either transparent (“1”) or opaque (“0”). A photomask may also be a phase-shift mask/photomask (PSM) in which higher resolution and increased DOF (Depth of Focus) is achieved by controlling the phase shift and the transmission rate of the electromagnetic radiation 10.

The advantageous aspects of the present technology apply to all different types of lithographic techniques and their respective masks/reticles, some examples of which are discusses above. More specifically, in a preferred set of embodiments, an instant conformal coating, such as coating 110 of FIG. 1 may be deposited, on a photomask that may be a binary photomask, a phase-shift photomask, a projection photomask, a contact photomask, a proximity photomask, or the like. In other embodiments, such a coating may be deposited on an EUV mask, in which case underlying substrate 102 would contain a multilayer (ML) as discussed further below. Alternatively, or in addition, it may be deposited on a reticle of a projection photomask or an EUV mask. Still in related embodiments, such a reticle may be housed or protected under a pellicle, as will be discussed further below.

Armed with the above knowledge, let us proceed further with FIG. 1 and the embodiments covered therein. Instant conformal coating 110 is deposited using an atomic layer deposition (ALD) process instead of the traditional chemical vapor deposition (CVD) processes of the prior art. As a result, coating 110 has an extremely uniform thickness across a large surface area of protected lithography mask 120. This is because as opposed to flow-dependent vapor deposition processes of traditional CVD, chemical processes involved in ALD are nucleation-based and self-limiting, resulting in depositing of coating 110 one atomic layer at a time.

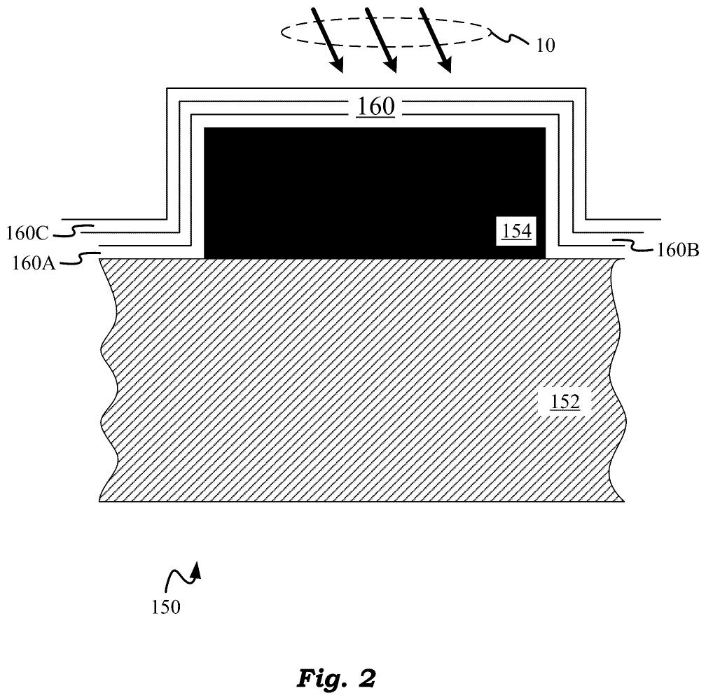

This is explicitly shown in FIG. 2 showing a cross-sectional view of a portion of a protected instant lithography mask 150. In the portion of mask 150 shown, an instant conformal coating 160 composed of individual atomic layers 160A, 160B and 160C is shown deposited on a pattern feature 154 over a substrate 152. The advantageous aspects of instant ALD based deposition of protective conformal coating 110 and 160 of photomasks 120 and 150 of FIG. 1 and FIG. 2 respectively are numerous. These include:
1. Protection from, or elimination/reduction of electrostatic arching: Without a protective coating as in the techniques of the prior art, electrostatic charge differential between islands of pattern 104/154 of FIG. 1/FIG. 2 could cause potential difference in the air to exceed breakdown threshold. This would cause electrostatic arching between those islands, resulting in damaging of the metallic pattern. This is also the case with the prior art of U.S. Patent Publication No. 2016/0342079 A1 to Oh referenced in the Background section. In this prior art technique, their protective layer is removed from the top or distal end of metallic pattern for producing their phase-shift mask, resulting in islands of electrostatic potential difference and consequent damaging arching between those islands of the pattern.

In contrast, a key benefit of the present technology is that with appropriate/controlled doping of its instant conformal coating, the conductivity and resistivity of the coating can be controlled. Thus, if electromagnetic absorbing pattern 104/154 of FIG. 1/FIG. 2 is embedded in coating 110/160 that is composed of an appropriately doped dielectric, also sometimes referred to as a “leaky dielectric”, the above electrostatic arching is prevented because of at least two reasons: (1) As a result of the bulk conductivity and charge redistribution because of the instant leaky dielectric, the electrostatic charge differential between various isolated parts/islands of the pattern ceases to exist, and (2) the breakdown voltage of the dielectric medium of coating 110/160 is much higher than air.

In preferred embodiments, coatings 110 and 160 of FIG. 1 and FIG. 2 respectively may be composed of an appropriately doped SiO2, Al2O3, etc. Thus, in addition to providing protection from mechanical damage, instant protective conformal coating 110/160 of FIG. 1/FIG. 2 protects underlying pattern 104/154 respectively from electrostatic (or simply put static) arching. Differently stated, instant protective conformal coating 110/160 provides mechanical as well as electrostatic protection to underlying pattern 104/154 respectively.
2. Uniformity of thickness: As an advantage of the present design, instant conformal coating 110/160 has an extremely uniform thickness across a large surface area of the mask because it is formed one atomic layer at a time. The mask can be 6 inches across while still resulting in coating 110/160 to be extremely uniform even after having deposited hundreds of layers, because of growing/depositing of the coating via ALD only one atomic layer at a time.

This is clear if we take advantage of FIG. 2. As noted above, FIG. 2 shows a portion or subsection of an instant protected lithography mask 150 with substrate 152 on which a feature 154 of an electromagnetic radiation absorbing pattern is shown. Per above, we may just use the reference numeral 154 to refer to the entire electromagnetic radiation absorbing pattern of mask 150 for reasons of brevity, with the knowledge that there may be many features of the pattern present on mask 150.

Further shown in FIG. 2 are just three distinct atomic layers 160A, 160B and 160C of an instant conformal protective coating deposited via ALD techniques. As shown in FIG. 2, resultant coating 160 is extremely uniform because it is formed or grown in an ALD chamber in a self-limiting manner, one atomic layer a time.
3. Uniform stochiometric composition: The chemical composition of coating 110/160 of FIG. 1/FIG. 2 is also extremely uniform. This results in a refractive index of the coating that is uniform across the entire surface area of the mask.
4. Index matching to substrate: The refractive index of protective conformal coating 110/160 of FIG. 1/FIG. 2 respectively can be precisely matched to the refractive index of the underlying substrate. If mask 120 or 150 of FIG. 1 or FIG. 2 respectively is an EUV mask, the underlying substrate comprises a reflective multilayer (ML) of the EUV mask per below discussion. In this case, the index matching may be done with the first or topmost layer of the ML.

Regardless, as a result of this index matching, there is no unwanted reflection of incident electromagnetic radiation 10 at the interface of conformal coating 110/160 and the underlying substrate (or ML). This reduces or eliminates any unwanted interference patterns at or near the interface, thereby eliminating undesired optical artifacts. For photomasks, this consequently means more high-quality printing and greater yield. The indices per above may be substantially matched, exemplarily up to 1/100^{th} decimal places or even lower.
5. No optical defects due to crystalline particles: Yet another advantage of the present technology is that since the ALD process is nucleation-based instead of gas-based CVD processes of the prior art, there is no formation and settling of spurious crystalline particles on the mask. Such crystalline particles would otherwise form in gas-phase and then rain down on the underlying surface. In the techniques of the prior art, these crystalline particles cause optical defects in the coating that result in defective features of the mask and eventually lower yield. However, there is no such build-up of crystalline particles in the present design and hence an improvement in feature production/quality and consequently greater yield.
6. High-quality step-coverage: Step-coverage refers to the property of the conformal protective coating to deposit evenly or uniformly on the top/tops or distal end/ends, as well as on the sides/sidewalls of the features of the pattern. Since an ALD grown coating is formed one atomic layer at a time, and since the process is self-limitation and nucleation-based, as a consequence, the deposited coating is even all around the pattern features.

This aspect of the present technology is clear from FIG. 1 explicitly showing step coverage 112 on the sidewalls or sides of pattern 104 to be of the same thickness as on the top or distal end. This is also clear from FIG. 2, where there are exactly three atomic layers 160A, 160B and 160C of instant conformal coating 160 on the sides as well as the top of pattern feature 154. This excellent step coverage results in high-resolution printing of the pattern in photolithography due to desirable phase-shift effects from smooth and uniform coating on the sidewalls of the pattern. Ultimately this results in higher quality product and greater yield. The techniques of the prior art oftentimes leave voids in any protecting layer which scatter light and affect image fidelity.
7. Stress and/or distortion free at a wide range of temperatures: Yet another key advantage of the present technology is that the conformal protective coating, such as coating 110 of FIG. 1 and coating 160 of FIG. 2 can by deposited via ALD at a wide variety or range of temperatures. This is in contrast to the typical CVD process of the prior art where extreme temperatures and vacuum conditions must be achieved to deposit a decent quality flow-based film. On the other hand, the instant protective coating may be grown via ALD even at room temperature. More specifically, the instant coating can be grown at temperatures between 20° C. and 80° C. The instant technology is able to achieve its results at such low temperatures because one of the precursors is activated by plasma, as taught per present and incorporated teachings.
8. Gradient coating: Still another benefit of the present technology over the prior art is that instant conformal coating can be grown to comprise of different materials or chemical species. This is because an ALD grown coating is deposited/grown one atomic layer at a time. With the desired combination of various precursors and chemical agents introduced into the ALD chamber, atomic layers of different compositions can be deposited as part of the instant conformal coating.

Therefore, while referring to the exemplary embodiment of the drawing of FIG. 2, atomic layer 160A-B may be of SiO2. Now, if instant protected mask 150 is to be processed in a particularly harsh application, or if a precise/rigorous index-matching of conformal coating 160 to underlying substrate 152 is required, then atomic layer 160C may be of a different material.

Of course, in practical applications, the number of such overlying and underlying layers of SiO2 and/or other materials may be more i.e. in dozens or hundreds or more. In a similar manner, any number and types of such layers may be deposited in a tapered manner one on top of another as an instant gradient conformal protective coating based on the instant principles.
9. Reduced light-scattering due to ultra-smooth surface of coating: Because the surface of the conformal protecting coating, such as coating 110 of FIG. 1 and 160 of FIG. 2, is extremely smooth, there is minimal light scattering from the surface of the coating. This results in reduced optical defects and higher image fidelity. This in turn results in better control of line widths of the printed image and consequently the speed of the device. This is especially important as smaller design rules are sought. Further, it improves printability of contact holes and thus minimizing of yield loss.
10. Plasma enhanced ALD (PEALD) or plasma-activated ALD (PAALD): In a set of highly preferred embodiments, the ALD process employed is plasma enhanced ALD (PEALD) or plasma-activated ALD (PAALD) accruing the consequent benefits of such a plasma-based design over standard ALD. As per the present and incorporated teachings, the instant technology is able to achieve the benefits of plasma-activation or plasma-assistance in its PEALD or PAALD embodiments. The present technology is able to able to do so without the plasma coming in contact with the substrate and damaging it.
11. Continuous-flow PEALD/PAALD: In still another set of highly preferred embodiments, the PEALD/PAALD is a continuous-flow process as taught in U.S. Pat. Nos. 9,972,501 B1, 10,366,892 B2 and 10,361,088 B2, all to Birol, and which are all incorporated herein by reference in their entireties. Therefore, these preferred embodiments accrue the consequent benefits taught in these references of continuous-flow PEALD/PAALD over standard PEALD/PAALD techniques.

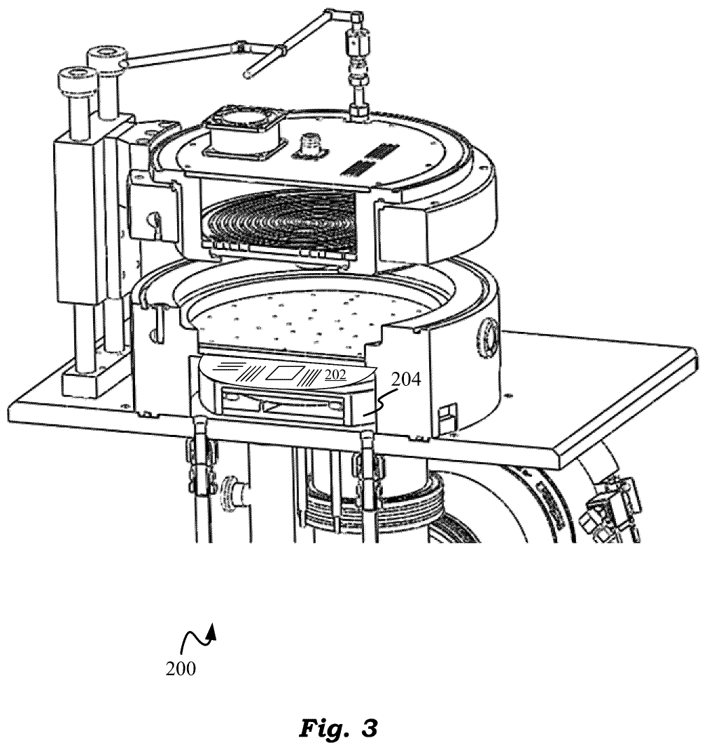

FIG. 3 shows a cross-sectional view of such a continuous-flow PEALD chamber assembly 200 in which a lithography mask 202 is being coated with nucleation-based atomic layers to form an instant conformal coating 110 or 160 as shown in FIG. 1 and FIG. 2 respectively. More specifically, FIG. 3 shows mask 202 on platen heater 204 of chamber assembly 200. For further details, the reader is referred to the above-mentioned references.

As taught in the above-mentioned references, since one of the attributes of the above continuous-flow process is that it cuts the cycle-time or process time dramatically i.e. approximately by half as compared to other techniques. Conversely, the present technology increases the throughput by a factor of 2. As a result, the present design reduces the probability of particles falling on the substrate also approximately by half, because the process/cycle-time is cut in half as well. This has the advantage of making instant coatings very defect-free. Furthermore, as noted above in the present design, the plasma does not contact the substrate and does not damage it due to its high-density ion flux.
12. Pelliclized lithography masks or reticles: Pellicles are typically used as dust covers to prevent particles falling onto the lithographic or electromagnetic radiation absorbing patterns of projection photomasks or EUV masks or reticles thereof. Since the particles are captured on top of the pellicle rather than on the pattern where the focal plane is, they do not print because of being out-of-focus. However, occasionally the pellicle gets damaged and needs to be removed and replaced. This process requires removal of the reticle frame glue and the cleaning of the mask.

Since the lithographic mask/reticle cannot typically be cleaned by brushing, it requires sending it back to the mask shop for cleaning and re-pelliclization. It is during this cleaning process that the mask/reticle is most vulnerable to damage. Also, current leading-edge devices have “matched” reticles belonging to a set of reticles for exposing the entire wafer. If one reticle is destroyed then the entire set of reticles needs to be replaced. This is extremely costly and cannot be done readily, thus causing costly interruption of production.

The present technology overcomes such a shortcoming of the prior art. More specifically, if the projection photomask or EUV mask or their reticle has an instant protective coating, such as coating 110 or 160 of FIG. 1 and FIG. 2 respectively, it can be quickly cleaned on-site and the mask/reticle can then be re-pelliclized. This is because the coating provides a robust protective layer for the projection mask/reticle.

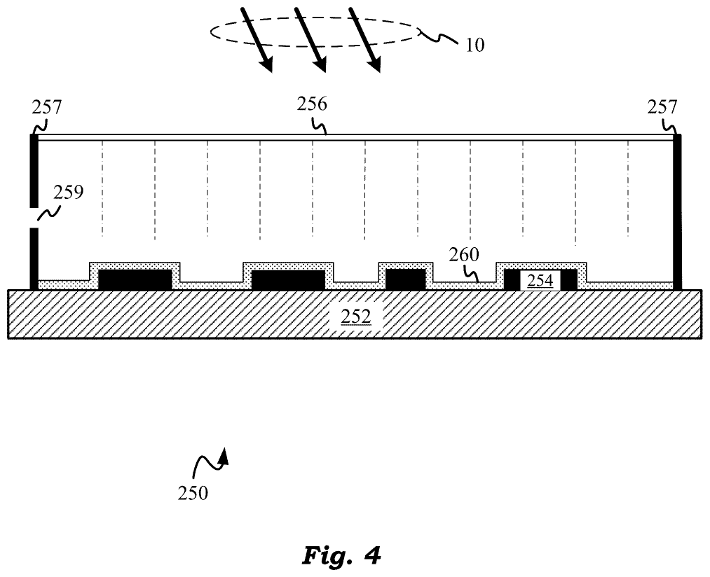

FIG. 4 shows in a cross-sectional view, a pellicle 256 covering/protecting an instant protected reticle 250 with an instant conformal coating 260 of the present teachings. Pellicle 256 has metallic rim or perimeter or sidewall 257. There is a hole 259 on one side of pellicle 256 to allow for equalizing the pressure between outside surroundings and the inside of the pellicle. Coating 260 is protecting a lithographic pattern 254 on an underlying substrate 252. Reticle 250 may be a part of a projection photomask or in other words it may be a projection reticle. Alternatively, reticle 250 may be an EUV reticle, in which case substrate 252 may be a multilayer (ML) substrate along with the various coatings/layers for EUV lithography known in the art. EUV masks/reticles are further discussed below in these teachings.

The advantages of the present technologies are also accrued by such pelliclized lithographic masks/reticles as shown in FIG. 4. Per above, once the pellicle is removed for cleaning, instant reticle 250 with its instant conformal coating 260 mechanically protecting the underlying pattern and reticle, may be cleaned on-site and re-pelliclized without having to send it back to the mask shop. This results in significant savings in operational costs, and improvements in yield and efficiencies.
13. Amenable to aggressive cleaning: Yet another benefit of the present conformal protective coating of the instant technology is that it can withstand very aggressive cleaning methods without incurring damage to itself or to the mask/reticle underneath. Such aggressive cleaning techniques include:
   a. Aggressive chemical cleaning even with the most aggressive Piranha solution.
   b. Abrasive brush cleaning. In addition to chemical cleaning, the present protective coating also allows for brushing of the protected mask/reticle, which may be an abrasive process and not possible without damaging the pattern in the absence of the instant coating. This is especially important during laser mask repair process in which a damaged lithographic mask is repaired with a laser beam. The laser beam is used to ablate unwanted metallic pattern particles from the substrate. However, during this process, the ablated metallic particles rain as debris on the mask and get settled thereon.

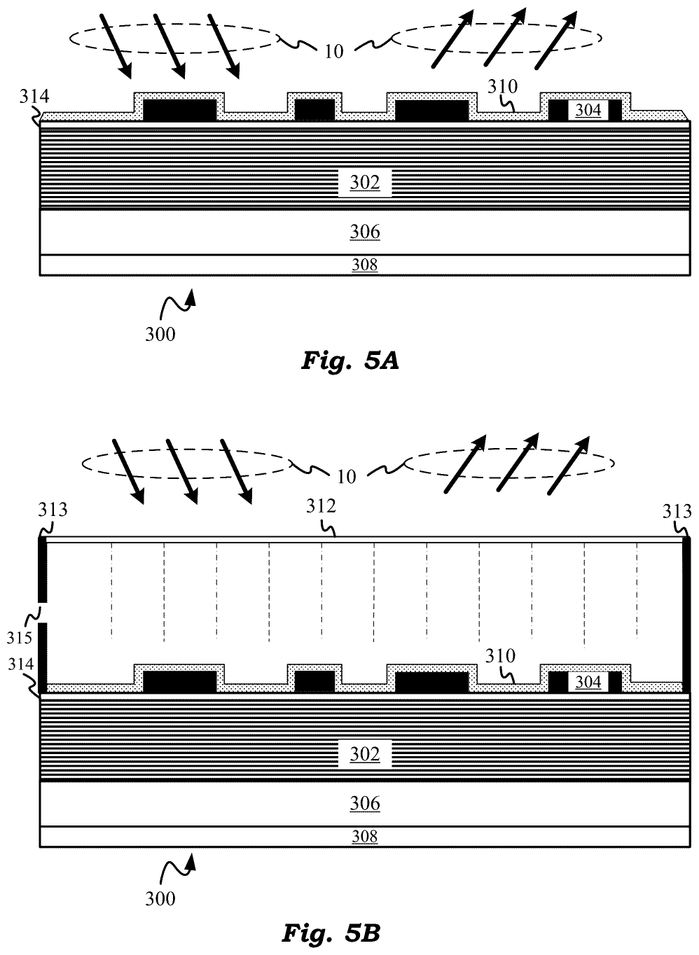

These rained/settled particles are subsequently hard to clean. However, if the mask is protected by an instant conformal protective coating that acts as a leaky dielectric, these ablated and rained/settled particles can be aggressively removed, for example, by brush cleaning or by aggressive chemical cleaning. This is because the particles are not held with electrostatic charge as a result of the leaky dielectric nature of the instant coating. Exemplary aggressive chemical cleaning in such a scenario include cleaning with buffered hydrofluoric acid (HFl).
14. Application to EUV lithography: Yet another advantage of the present technology is that it is very suitable for protecting next-generation EUV lithography masks. Such an embodiment protecting an EUV mask or its reticle by an instant conformal coating of the above teachings is shown in the cross-sectional views of FIG. 5A-B.

More specifically, FIG. 5A shows protected EUV mask 300 that comprises of the typical layers or parts of a traditional EUV mask, namely a backside coating 308, a low thermal-expansion (LTE) substrate 306, a reflective silicon-molybdenum (Si/Mo) multilayer (ML) 302, a capping layer 314 and a pattern mask 304 composed of a suitable absorber material such as tantalum (Ta) or tungsten (W). However, unlike a traditional EUV mask, protected EUV lithography mask 300 of FIG. 5A has the additional layer 310 which is an instant conformal protective coating deposited by ALD on top of pattern 304 and underlying mask per prior teachings.

Because an EUV mask is a reflective mask, incident electromagnetic radiation 10 is reflected back off mask 300 as shown. The lithographic pattern itself is defined in an absorber layer/material 304 on top of the multilayer stack as shown. This absorber is typically made of a material such as tantalum-based compounds. The pattern in the absorber selectively blocks or allows EUV light to reflect off mask 300 in specific areas, creating the necessary image for lithography.

Typically, an EUV mask is slightly curved for facilitating convergence of incident EUV rays. The reflectivity of the EUV mask results from its multilayers. The reflective EUV mask typically demagnifies/reduces the printed image by 4:1 as result of various optical elements such as mirrors employed in the setup. Sometimes substrate 306, ML 302 and capping layer 314 are collectively referred to as the substrate. Absorbing/absorber pattern 304 is especially suited for absorbing extreme ultraviolet (EUV) electromagnetic radiation 10 with wavelength of 13.5 nm, also sometimes referred to as “soft” x-rays.

EUV or soft x-ray electromagnetic radiation 10 incident on lithography mask 300 is absorbed by pattern 304 where it is present, and reflected my ML reflective layer 302 where there is no absorbing pattern 304. Ultimately, pattern 304 and more specifically its “negative” is printed to a wafer, or portion thereof if mask 300 is actually an EUV reticle. The mask/reticle with its photoresist is then developed. EUV lithography holds great promise because of its ability to print extremely small feature sizes.

However, an EUV mask must undergo strenuous inspections throughout manufacturing and printing process, in order to ensure that it is defect-free and also free from undesired particles or impurities. Especially ML layer 302 with its many alternating constituent layers is prone to entrapping particles, resulting in fabrication defects and lower yields. The present technology improves EUV lithography by protecting an EUV mask including its lithographic pattern 304 by a protective conformal coating 310 shown in FIG. 5A. In addition to the benefits of instant protective conformal coating techniques discussed above, let us discuss their benefits as they apply to EUV lithography. As such, the advantages of an instant coating 310 for a protected EUV lithography mask 300 are:
a. Mechanical protection: In addition to providing electrostatic protection per above, conformal coating or film 310 mechanically protects the underlying mask. Because the instant conformal coating acts as a leaky dielectric, any deposited particles are easily blown off and are cleanable by aggressive cleaning techniques because they are not held by electrostatic charge.
b. No attenuation: Coating 310 can be made extremely thin via ALD, thereby causing no attenuation of the incident EUV rays. Exemplarily, coating 310 can be just 10 Å high/thick which is just a fraction of 13.5 nm wavelength of the incident ultraviolet electromagnetic radiation or soft x-rays 10. This results in negligible attenuation of the incident radiation. Such a 10 Å layer can be deposited using ALD one atomic layer at a time. For example, one atomic SiO2 layer is approximately 2 Å thick. So, in our example above, the 10 Å monolayer would just require 5 atomic layers of SiO2.
c. Index matching: Per above, because instant conformal coating 310 can be grown to be very thin as compared to the wavelength of the incident EUV rays, coating 310 does not affect the EUV rays in any way that would adversely affect the eventual printing of mask 304 on the wafer. Therefore, it may not be necessary to match the index of coating 310 to underlying capping layer or ML.
d. Thin coating and better EUV inspections: Some EUV defects do not show under optical wavelengths. Therefore, inspections of EUV masks under EUV rays is also required. Because instant conformal coating is very thin, it does not absorb enough EUV rays to adversely affect or prevent such EUV inspections.
e. Sacrificial coating: Coating 310 may also be made sacrificial. In other words, once protected EUV mask 300 has been manufactured, or once the requisite inspections have taken place, coating 310 may be removed, for example, by plasma etching in a suitable reactor.

Based on above, a preferred EUV mask architecture based on the present technology employs depositing a thin instant protective coating on an EUV mask blank. The blank is then inspected for any trapped particles or imperfections under optical light. Afterwards, the initial protective coating may be removed, for example by etching. Alternatively, the initial instant protective coating is left on the EUV blank.

Regardless, lithographic patterning is then performed by depositing the absorber material. Finally, another thin instant conformal protective coating is deposited with its benefits described herein. Because the instant coating is very thin and uniform, it does not prevent/affect any EUV inspections that are then performed during production. This is so, even if the initial protective coating is left on the mask blank per above. For EUV lithography, instant conformal protective coating may be made from materials other than SiO2, such as Al2O3, etc.
f. Pelliclization: As in the case of a photomask, an EUV mask or a reticle may also be pelliclized. Such a pelliclized EUV embodiment is shown in FIG. 5B where protected EUV mask/reticle 300 of the present design is protected under a pellicle 312 with a metallic sidewall or perimeter/rim 313 as shown. There is a hole 315 on a sidewall of pellicle 312 for equalizing the pressure between the inside and the outside of the pellicle. The above advantages of the present technology are also accrued when the EUV mask/reticle is thus protected under the pellicle. Pellicle 312 complements coating 310 by protecting the focal plane of mask 300 by stopping particles on the pellicle, rather than letting them deposit on mask 300 or its protective conformal coating 310.

Furthermore, EUV pellicles, such as pellicle 312 of FIG. 5B, may be made out of thin inorganic films which can sometimes break. In such a scenario, because lithographic pattern 304 is protected by instant protective conformal coating 310, it allows removal of the particles and debris that had landed on it due to the pellicle breakage, without harming underlying pattern 304.

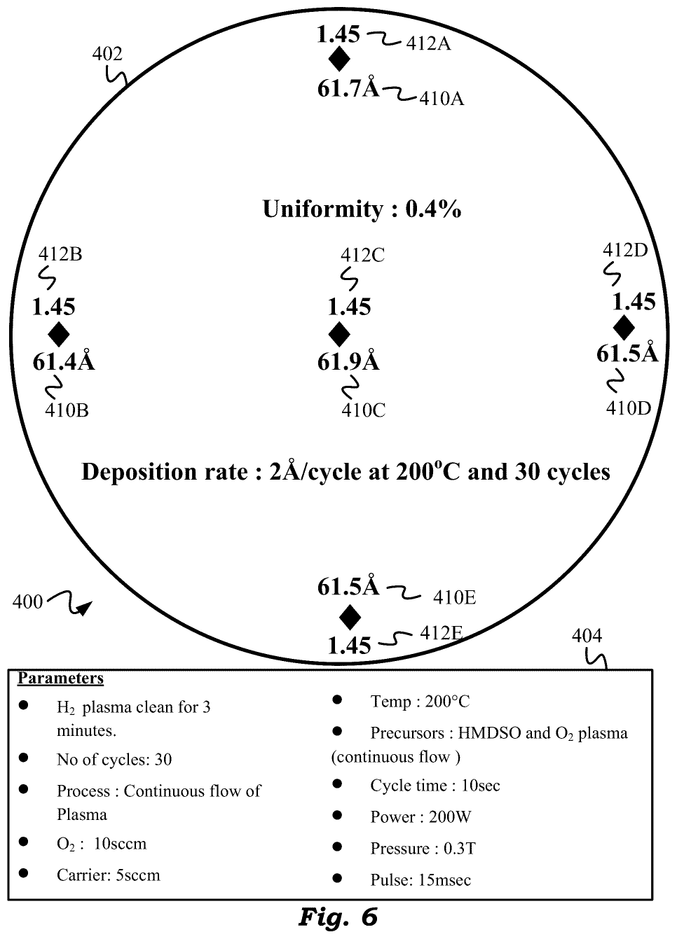

To further elucidate the benefits of the instant design over traditional art, FIG. 6 shows a dataset 400 from an exemplary implementation of the present technology, depositing SiO2 at 200° C. on a lithography mask using continuous-flow PEALD chamber assembly 200 shown earlier in FIG. 3. In this experiment SiO2 is deposited on a wafer indicated by circle 402 via continuous-flow PEALD/PAALD using parameters shown by box 404. The observed thickness and refractive index of the resultant instant conformal protective coating at various locations indicated by black diamonds of a 6-inch diameter wafer are indicated as shown.

More specifically, thickness values 410A, 410B, 410C, 410D and 410E at top, left, center, right and bottom locations respectively of the wafer as measured in the experiment are indicated. Similarly, refractive index values 412A, 412B, 412C, 412D and 412E at top, left, center, right and bottom locations respectively of the wafer as measured in the experiment are indicated.

From FIG. 6, it can be clearly seen that the present technology produces an extremely uniform thickness at 200° C. with a uniformity variation (or simply uniformity) of only 0.4% across the 6-inch diameter as shown. This value is calculated by subtracting the lowest thickness on the wafer from the highest thickness and dividing the resultant value by a mean of all thickness values.

The coating techniques of the present technology as shown in the experiment of FIG. 6 for a wafer are now extended to a mask or reticle. The result is the deposition of a uniform protective coating on the mask/reticle with properties similar to those shown in FIG. 6. Such a uniform thickness of instant conformal coating affords many benefits as taught above. The present technology also produces an extremely uniform stoichiometric or chemical composition of the coating as compared to the techniques of the prior art. This is proved by refractive index values 412A-E that are identical across the various locations indicated by black diamonds on mask/reticle 402.

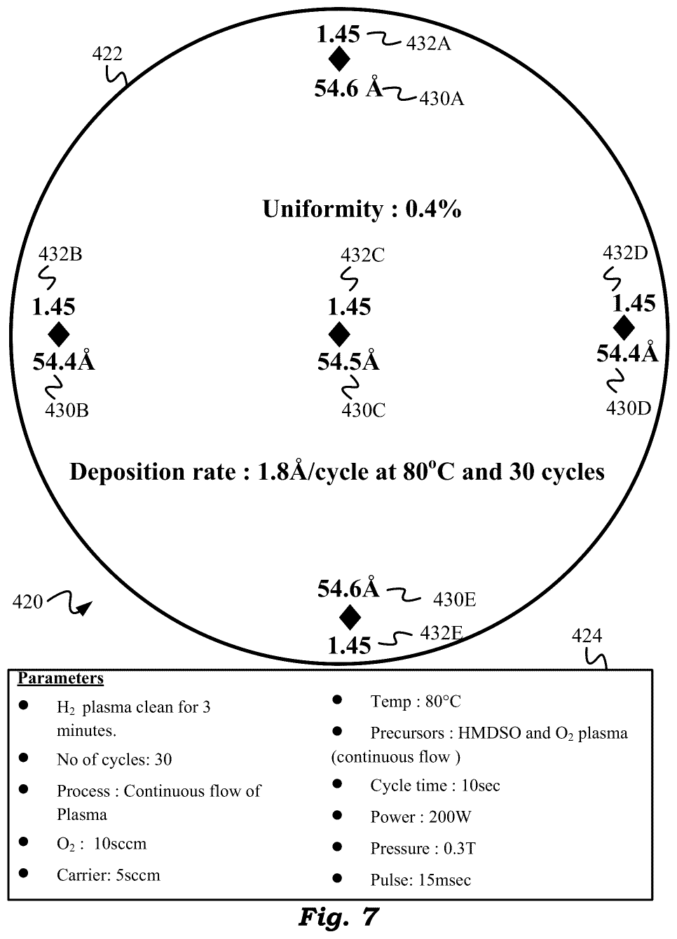

In a similar manner, FIG. 7 shows a dataset 420 from an exemplary implementation of the present technology, depositing SiO2 at 80° C. on a wafer using continuous-flow PEALD per above teachings. In this experiment SiO2 is deposited on the wafer indicated by circle 422 via continuous-flow PEALD/PAALD using parameters shown by box 424. The observed thickness and refractive index of the resultant instant conformal protective coating at various locations indicated by black diamonds of a 6-inch diameter mask/reticle are indicated as shown.

More specifically, thickness values 430A-E at top, left, center, right and bottom locations respectively of the mask as measured in the experiment are indicated. Similarly, refractive index values 432A-E at top, left, center, right and bottom locations respectively of the mask/reticle as measured in the experiment are indicated. As before, the coating techniques of the present technology as shown in the experiment of FIG. 7 for a wafer are now extended to a mask or reticle.

From FIG. 7, it can be clearly seen that the present technology produces an extremely uniform thickness even at only 80° C. with a uniformity variation of only 0.4% across the 6-inch diameter as shown. Such a uniform thickness coating affords many benefits as taught above. In an analogous fashion, the present technology produces the coating to have an extremely uniform stoichiometric or chemical composition over techniques of the prior art. This is proved by refractive index values of 432A-E that are identical across the various locations indicated by black diamonds on mask/reticle 422.

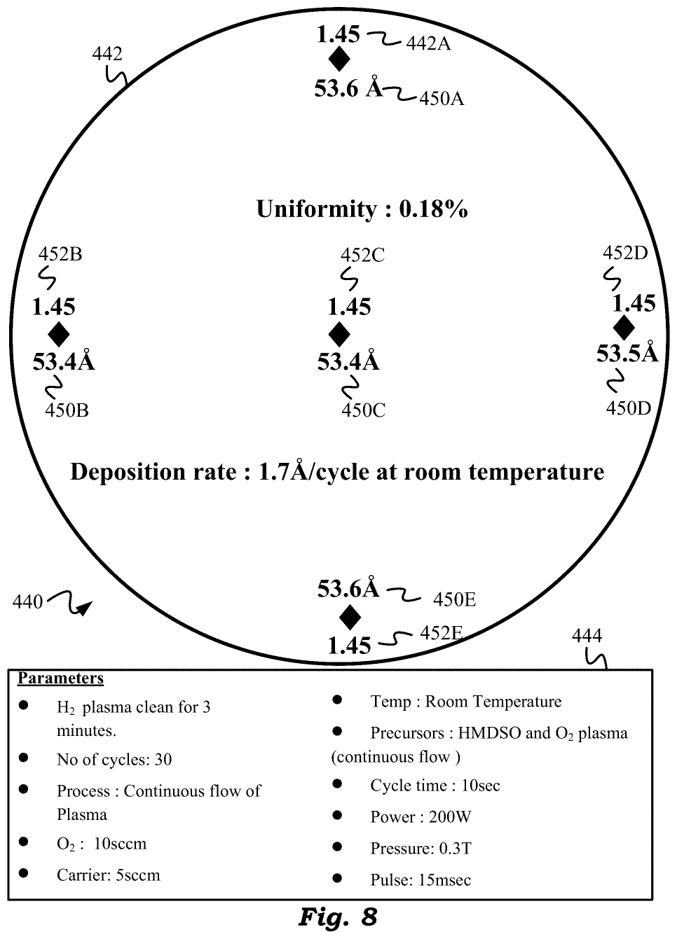

FIG. 8 shows yet another dataset 440 from an exemplary implementation of the present technology, depositing SiO2 at room temperature (in the range of 20-25° C.) on a photomask using continuous-flow PEALD per above teachings. In this experiment SiO2 is deposited on a wafer indicated by circle 442 via continuous-flow PEALD/PAALD using parameters shown by box 444. The observed thickness and refractive index of the resultant instant conformal coating at various locations indicated by black diamonds of a 6-inch diameter lithography mask/reticle are indicated as shown.

More specifically, thickness values 442A-E at top, left, center, right and bottom locations respectively of the mask/reticle as measured in the experiment are indicated. Similarly, refractive index values 442A-E at top, left, center, right and bottom locations respectively of the mask/reticle as measured in the experiment are indicated. As before, the coating techniques of the present technology as shown in the experiment of FIG. 8 for a wafer are now extended to a mask or reticle.

From FIG. 8, it can be clearly seen that the present technology produces an extremely uniform thickness even at room temperature with a uniformity variation of only 0.18% across the 6-inch diameter as shown. Such a uniform thickness coating affords many benefits as taught above. In an analogous fashion, the present technology produces the coating to have an extremely uniform stoichiometric or chemical composition over techniques of the prior art. This is proved by refractive index values 442A-E that are identical across the various locations indicated by black diamonds on mask/reticle 442.

### Employing Hydrogen as a Dopant in the Instant Conformal Coating:

Let us now review a set of highly preferred embodiments that further enhance the properties of the instant conformal coating by using hydrogen as a doping specie or as a doping agent or as a dopant. By controlling the amount of hydrogen, the amount of “leakiness” of the dielectric nature of the coating can be controlled. In other words, by controlling the amount of hydrogen embedded in the coating, one can alter the resistivity or alternately the conductivity of the dielectric coating as desired. Hydrogen also has excellent optical properties. In other words, it does not impart or produce any crystalline particles in the coating. Such crystalline particles would otherwise produce optical defects in the mask that would reduce the yield or economic efficiency of the operation per above discussion.

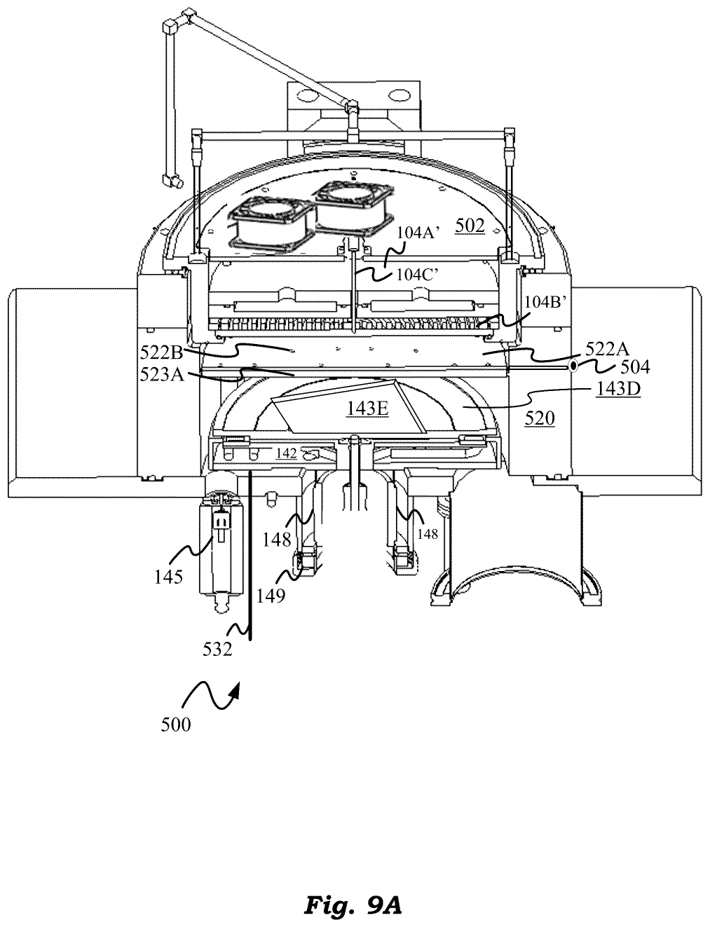

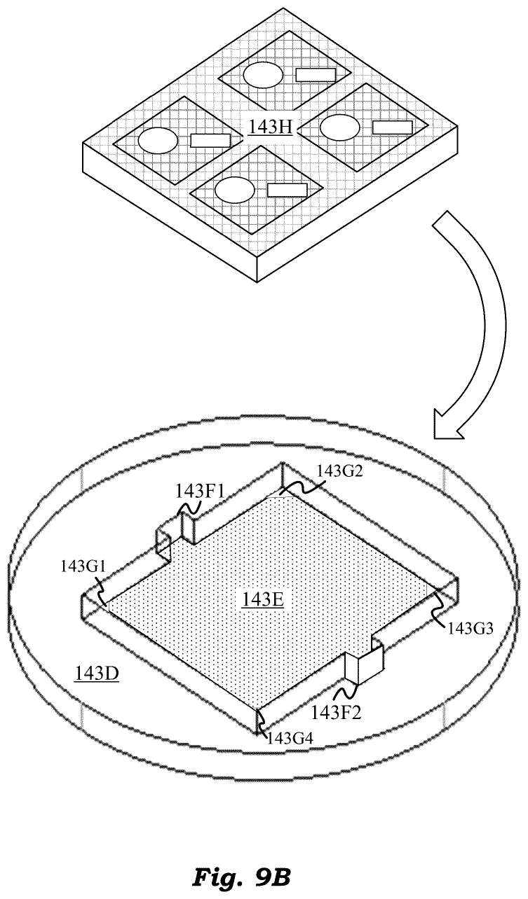

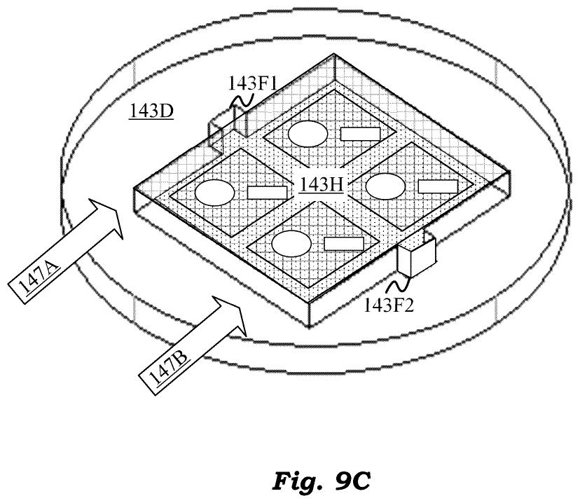

In order to incorporate hydrogen in an informal coating of the present design, a hybrid or specialized PEALD reactor based on the instant principles is employed. Such a hybrid PEALD chamber or equipment or reactor 500 is shown in FIG. 9A. FIG. 9A shows a PEALD chamber or reactor that is a variation of the hybrid reactor of FIG. 18 shown and taught in incorporated by reference U.S. Pat. No. 11,087,959. Hybrid reactor 500 of the present embodiments is especially suited for depositing an instant conformal coating with hydrogen as the doping agent. A key difference in reactor 600 shown in FIG. 18 and discussed in the incorporated by reference U.S. Pat. No. 11,087,959, and instant reactor 500 of FIG. 9A is an electrical input or connection 532 to the platen as discussed in detail further below.

Let us now discuss in detail the workings of reactor/chamber 500 and see how one can effectively incorporate hydrogen in a conformal coating of the present design. Continuing to take advantage of FIG. 9A, we see that it illustrates a 3-D cross-sectional view of reactor 500 in its closed position. Cylindrical chamber 500 has an upper portion 502 and a lower portion 520 corresponding to upper portion 502 and lower portion 520 of chamber 600 of FIG. 18 of incorporated by reference U.S. Pat. No. 11,087,959 of which instant chamber 500 is a variation. There is also a metal plate 522A with holes 522B aligned with the holes 523B (not visible in FIG. 9A) of an underlying ceramic plate 523A of the incorporated teachings. Only one hole of metal plate 522A is shown marked by reference numeral 522B in FIG. 9A in order to avoid clutter.

The rest of the applicable elements and their reference numerals of rector 500 of FIG. 9A are the same as the elements and their reference numerals of reactor 600 of FIG. 18 of incorporated by reference U.S. Pat. No. 11,087,959. The exceptions are that reference numerals 104C, 104A and 104B (designating RF connection 104C to ICP source 104A with its coil/antenna 104B) have been relabeled to 104C′, 104A′ and 104B′ respectively in order to differentiate them from drawing elements 104A-C of FIG. 1 of the instant specification. Furthermore, there is an electrical connection 532 connected to the platen with surface 143D. We may refer to the platen with its top surface 143D simply as platen or as ALD plate 143D. Furthermore, FIG. 9A does not show or need rotating elements 524 of reactor 600 of FIG. 18 of incorporated by reference U.S. Pat. No. 11,087,959, as will be discussed further below. Not all the elements from FIG. 18 of incorporated by reference U.S. Pat. No. 11,087,959 have been marked in instant FIG. 9A in order to avoid distraction from the main principles being taught.

Also shown in FIG. 9A is a recess 143E on ALD plate or platen 143D in which a lithography mask is placed, such that the upper surface of the mask is coplanar with surface 143D of the platen. This aspect of the present design is further detailed in FIG. 9B and FIG. 9C. More specifically, FIG. 9B shows a lithography mask 143H with four lithographic patterns as shown. As shown by the curved block-arrow, mask 143H sits or is placed in recess 143E of ALD plate 143D. Exemplarily, mask 143H is on a quartz substrate. There are also two notches 143F1 and 143F2 that facilitate a mask holder (not shown) in placing mask 143H in recess 143E and for taking it out of the recess.

Furthermore, there are four small polytetrafluoroethylene (PTFE) corner steps or inserts 143G1, 143G2, 143G3 and 143G4 in recess 143E as shown. The purpose of these inserts is so that when mask 143H is placed in recess 143E, only its four corners contact PTFE corner inserts 143G. This is so that the bottom of mask 143H does not touch the ALD plate in order to avoid picking up contaminants and baking them into the back of the mask. Exemplarily, inserts 143G are 1 millimeter high. FIG. 9C shows mask 143H seated in recess 143E of ALD plate/platen 143D.

FIG. 9C also shows the horizontal flow of precursors indicated by block arrows 147A and 147B. The precursors may enter the ALD chamber via inlets on the side of the chamber. Such inlet ports 126B were taught in the incorporated by reference U.S. Pat. No. 11,087,959. The pump-down and venting operations of the chamber are preferably performed slowly or gradually in order to avoid/reduce turbulence caused by eddies that would otherwise transfer contaminant particles onto the mask surface.

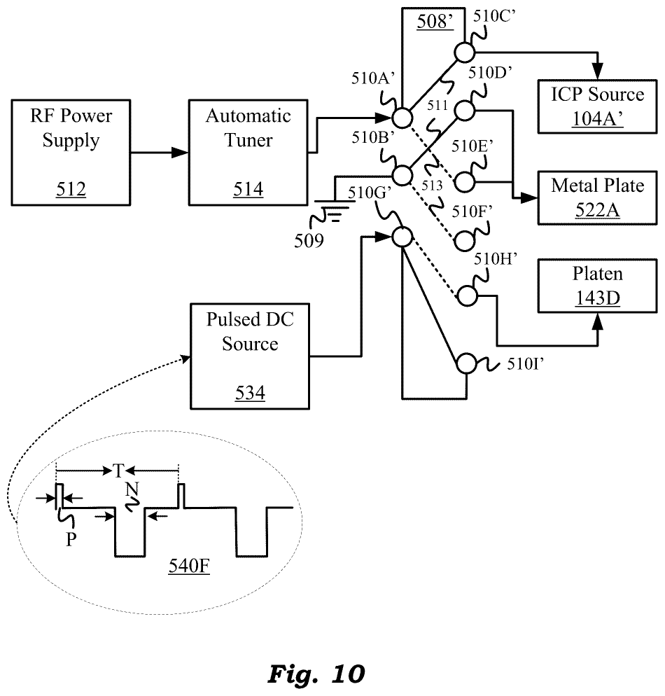

While reviewing FIG. 9A-C, in a manner similar to the embodiments discussed in reference to FIG. 18 of incorporated by reference U.S. Pat. No. 11,087,959, RF connections 104C′ and 504 supply RF power to ICP source 104A′ and metal plate 522A respectively. These RF connections are in turn fed/supplied from an RF switch. FIG. 10 shows a variation of the RF switch configuration of FIG. 17 of incorporated by reference U.S. Pat. No. 11,087,959 that is used to provide switching in the present embodiments. More specifically, triple pole triple throw (TPTT) RF switch 508′ shown in the schematic diagram of FIG. 10 feeds or supplies ICP source 104A′, metal plate 522A and platen 143D respectively of reactor 500 of FIG. 9A.

RF switch 508′ is in turn fed/supplied by an RF power supply 512 with an optional auto-tuner 514 from the above-incorporated teachings. Another input to switch 508′ is electrical ground 509 as shown. According to the chief aspects of the present embodiments, there is also a pulsed DC source 534 with an output voltage waveform 540F shown in the dotted oval shape in FIG. 10. TPTT witch 508′ routes the RF signal from RF power supply 512, electrical ground 509 and pulsed DC source 534 from its input ports 510A′, 510B′ and 510G′ respectively to its output ports 510C′, 510D′ and 510I′ respectively in switch position 511 shown by solid lines in FIG. 10.

In the alternate position 513 of TPTT switch 508′ shown by the dashed lines, input ports 510A′, 510B′ and 510G′ are connected to respective output ports 510E′, 510F′ and 510H′. This routing is performed electrically/electronically in response to control inputs that may be provided programmatically based on computer-generated/software signal(s) delivered to switch 508′. Note that output ports 510F′ and 510I′ of TPTT switch 508′ remain unused in the implementation shown in FIG. 10. TPTT RF switch 508′ may be electromechanical in construction using relay(s) or it may be a solid-state device and thus purely electrical. Moreover, alternate configurations for routing the RF signal, electrical ground 509 and DC pulsed source 534 are conceivable, such as by using three single pole single throw (SPST) switches, among others.

After having discussed the design of the present hybrid embodiments, let us now look at their operation based on the instant principles. When the control inputs of TPTT switch 508′ (not shown in FIG. 10 but presumed to exist), preferably activated by a computer program, are such that it is in position 511, then this mode of operation proceeds as per the PEALD techniques taught in prior and incorporated embodiments above. In other words, in this PEALD phase of the operation, the configuration apparatus/reactor 500 of FIG. 9 is used to deposit a conformal coating on a lithographic mask as described in the above teachings. By way of example, such a coating consists of or includes SiO2.

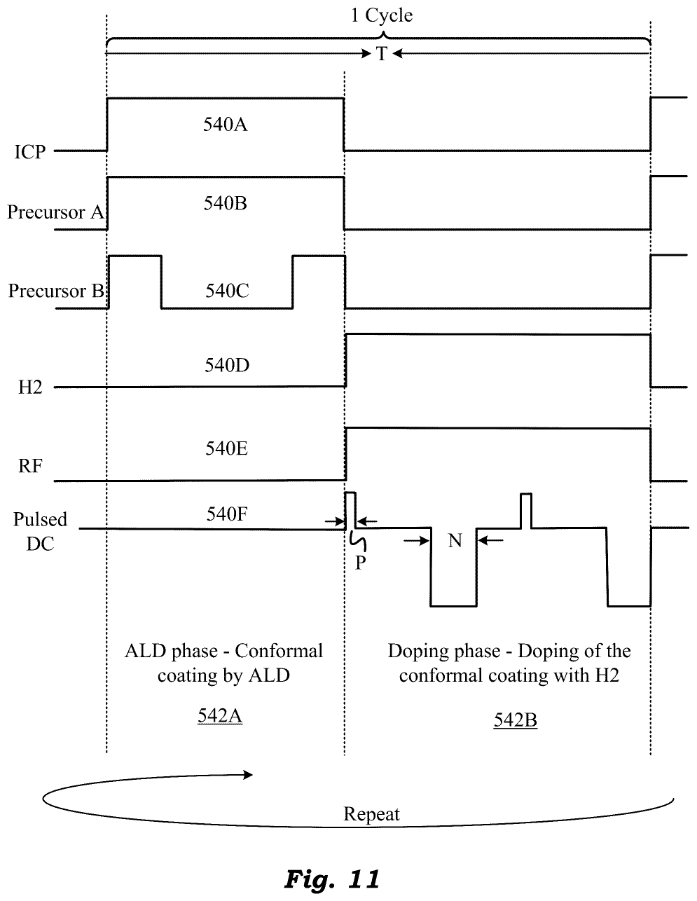

Referring to the timing diagram shown in FIG. 11, the PEALD phase is performed during time interval 542A. In this PEALD phase, switch 508′ is in position 511 with its input port 510A′ carrying the RF signal from RF power supply 512 and optional auto-tuner 514 to ICP source 104A′. Simultaneously, its input port 510B′ grounds metal plate 522A at ground potential 509. As such, metal plate 522A terminates the plasma generated by ICP source 104A′ in chamber 500 while allowing excited neutrals of reactants or gas(es) from above to pass through its holes 522B and then through smaller holes 523B (not shown) of ceramic plate 523A of FIG. 9A.

The above facilitates a self-limiting ALD reaction between the excited neutrals of the gas(es) pumped from above via feedthroughs and the gas(es) pumped from below and the substrate or the surface of lithography mask per prior teachings. Such a self-limiting reaction results in the formation of an atomically-sized PEALD film on the mask. In the preferred embodiment, such a film consists of or includes SiO2. During this PEALD phase, pulsed DC source 534 is connected to output port 510I′ by switch 508′ and is thus not used.

Explained even further detail, a suitable plasma gas/precursor A, e.g. O2 or H2, is flowed from above into the chamber and a suitable precursor/gas B for SiO2 is flowed or pulsed into chamber 500 via feeding lines from below the chamber per prior teachings. Exemplarily, a suitable precursor for SiO2 may be Hexamethyldisiloxane (HMDSO). Once a desired number of monolayers of the ALD film of SiO2 have been deposited on the substrate, the precursors are switched off. The above operation is characterized by interval 542A in the timing diagram shown in FIG. 11. In interval 542A of the timing diagram of FIG. 11, waveform 540A depicts the timing of the powering of ICP source 140A′. Waveforms 540B and 540C depict the timing of precursors A and B respectively into the chamber. During interval 542A, TPTT switch 508′ of FIG. 10 is in the position characterized by solid lines 511. Consequently, a desired number of monolayers of SiO2 film are deposited onto a lithographic mask of the present embodiments.

Now the operation switches over to the doping phase shown by time interval 542B in FIG. 11 where TPTT switch 508′ is switched to the position characterized by dashed lines 513 in FIG. 10. Now ICP source 104A′ and precursors A and B are programmatically switched off per waveforms 540A-C shown in FIG. 11. Simultaneously, as shown by waveform 540D in FIG. 11, H2 gas is flowed into the chamber. In one embodiment, H2 is flowed from below into the chamber. For this purpose, appropriate feeding lines of the above-incorporated teachings may be utilized. These lines are not visible in the view of reactor 500 shown in FIG. 9A but are presumed to exist.

Concurrently, and as a result of position 513 of switch 508′, RF power from RF power supply 512 and optional auto tuner 514 to metal plate 522A is turned on as characterized by waveform 540E in FIG. 11. Preferably, the RF power supplied by RF power supply 512 to metal plate 522A is at a much lower level than to ICP source 104A′ when switch 508′ was in switch position 511. This is because we want to further minimize and/or avoid the possibility of the ion flux in the plasma from damaging the underlying surface during the doping phase. Preferably, the RF power supplied to metal plate 522A during doping phase of time interval 542B is in the range of 50-100 watts while the RF power supplied to ICP source 104A′ during ALD phase in time interval 542A is in the range 500-1000 watts.

During time interval 542B, pulsed DC source 534 with waveform 540F is now connected to heated platen 143D by switch 508′ via electrical connection/input 532 of FIG. 9A. Consequently, a controlled amount of H2 is physically absorbed into the SiO2 layer on the mask during time interval 542B. Then the operation is switched back to time interval 542A and then again to 542B and this process is repeated a desired number of cycles. The process continues until a desired thickness of SiO2 conformal coating with the desired amount of H2 doping has been realized.

In the preferred embodiment, the operation is stopped between time intervals 542A and 542B and a measurement of the resistivity or alternately conductivity of the surface of the coating is performed. Then the doping phase may be commenced depending on whether the desired level of resistivity and consequently “leakiness” of the coating has been realized.

According to the instant principles, during time interval 542A when switch 508′ is in position 511, the operation proceeds as a continuous-flow PEALD process of the prior teachings for depositing SiO2 layer on a lithographic mask. During this phase, plasma gas/precursor A is continuously flowed into the chamber.

Gases introduced from feedthroughs above ICP source 104A′ will be under higher pressure than the same gases once they have traveled through the instant sparse showerhead holes 522B and 523B (not shown in FIG. 9A) of metal plate 522A and ceramic plate 523A respectively. The lower pressure of these gases below ceramic plate 523A will facilitate formation of plasma around the substrate. As in the prior embodiments, in the present embodiments also, platen 143D is preferably heated by a platen heater 142 shown in FIG. 9A. Though the substrate may only be heated to near room temperature the heat is distributed uniformly.

Note that for performing ALD based on instant principles, rotation of the platen is not necessary because one gets uniformity without rotation. This is because of the self-limiting nature of the ALD reaction. This also avoids/reduces turbulence as horizontal flow of gases hits the edge of the ALD plate/platen, resulting in a more laminar flow of gases. That is why, reactor of FIG. 9A does not explicitly show the rotating elements of the reactors of the incorporated teachings.

Now, when the operation switches to time interval 542B and switch 508′ is in position 513, plasma gas A is switched off and metal plate 522A is RF-powered. The RF power excites low-pressure H2 flowed into the chamber from below, thereby ionizing it and forming an H2 plasma above the coating/substrate. Then, as a result of pulsed DC source with waveform 540F applied to platen 143D via connection 532, H atoms are incorporated into the SiO2 coating on the mask.

Intuitively, this occurs because during the positive pulse/portion P of waveform 540F shown in FIG. 10-11, platen 143D is positively charged thus attracting electrons from H2 plasma above and neutralizing the surface charge on the substrate. For this purpose, the width of the positive part P is kept as a small percentage of the length T of the overall cycle-time T shown in FIG. 11. Exemplarily T is substantially 50 milliseconds (ms) long. Exemplarily, the width of positive pulse P is 1-5% of the over length T of the cycle and is thus substantially 1-5 ms long. Furthermore, since electrons are very mobile, the height or the value of pulse P indicative of the amount of positive voltage or potential applied to platen 143D need not be very high. Exemplarily, the value of P is substantially in the range of 5 volts (V) to 10 V.

Now, during the negative pulse N of waveform 540F, H+ ions from the H2 plasma are attracted and implanted into the coating on the mask. Since H+ ions or protons are much heavier than electrons, the height of pulse N indicative of the amount of negative voltage/potential applied to platen 143D may be higher than the value of P. Exemplarily, the value or depth of N is substantially in the range of −10 V to −20 V i.e. the absolute value of N is substantially in the range of 10-20 V. Additionally, since electrons are much more mobile than H+ ions, the duration of pulse P is much shorter than pulse N in order to attract equal number of electrons for surface charge neutralization. As a result of this potential difference, H+ ions are attracted at a high speed or sprayed or bombarded onto the coating on the mask, thereby embedding or incorporating themselves in it.

Thusly, hydrogen or H2 is doped or incorporated in/into the instant conformal coating to render it its dielectric properties per above teachings. The amount of hydrogen doping can be accurately controlled by controlling the width of the N pulse of waveform 540F. Unlike reactive ion etching (RIE) systems, the amount of negative voltage of pulse N is not so high so as to cause etching or ablation of the coating.

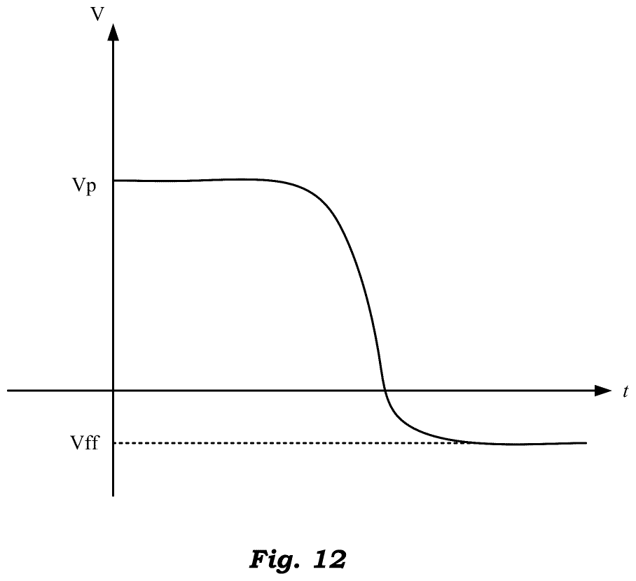

FIG. 12 shows a curve with respect to time t of potential difference or voltage V between the potential Vp of H2 plasma and potential/voltage Vff of the surface of an instant coating over the mask. Vff represents the overall negative self-bias of the surface because the number of electrons from the plasma that are attracted to the surface of the coating is much higher than the number of H+ ions. The H+ ions are accelerated towards the coating surface under a potential difference of Vp−Vff and sprayed/bombarded onto the coating as a dopant without chemically reacting with the coating. Such an H2 doping of the coating causes it to act as a leaky dielectric with a number of highly desirable properties than the coatings of the prior art.

As mentioned, there are many desirable properties afforded to an instant conformal coating by using hydrogen as a doping specie. These include much better electrostatic charge protection than by using any other dopants. Hydrogen doped coating provides this advantage as a result of much better bulk conductivity and charge redistribution across the coating. The benefits of H2 doped coating also include elimination of voids in the coating. The benefits also include elimination of spurious crystalline particles that would render optical defects in the coating. Such optical defects would cause negative impact to the efficacy of the lithography mask and ultimately to the manufacturing yield.

In a commercial setting, even a single defect comparable to the applied design rules is not acceptable as it will compromise all the chips and turn the yield to zero. Therefore, the H2-doped coatings of the present embodiments taught above provide effective systems and methods of eliminating such defects. Since hydrogen is the smallest atom, it can be implanted in an instant coating per the above-taught embodiments without causing any damage to silicon and oxygen bonds therein. The density of the implanted/doped hydrogen per present embodiments need not be very high in order to impart conductive/“leaky” properties to the instant coating. Preferably, the density of hydrogen doped in the instant coating based on the above teachings is substantially 10\hat{ }7 atoms/cubic centimeter (cc).

All the relevant and applicable teachings of the prior embodiments also apply to the present embodiments employing H2 as a dopant in the instant conformal coating.

In view of the above teaching, a person skilled in the art will recognize that the apparatus and methods of invention can be embodied in many different ways in addition to those described without departing from the principles of the invention. Therefore, the scope of the invention should be judged in view of the appended claims and their legal equivalents.

What is claimed is:

1. A method comprising the steps of:
(a) depositing by plasma enhanced atomic layer deposition (PEALD), a conformal coating on all sides and a distal end of a pattern existing on a substrate of a lithography mask, said pattern meant for absorbing electromagnetic radiation incident on said lithography mask;
(b) retaining said conformal coating on said all sides and said distal end for protecting said pattern;
(c) said PEALD performed by placing said substrate atop a platen inside a chamber, said chamber further having a planar inductively coupled plasma (ICP) source laterally affixed at its distal end from said substrate;
(d) isolating said substrate from said ICP source in said chamber by a metal plate laterally affixed above said substrate and a ceramic plate laterally affixed below said metal plate but above said substrate, said metal plate and said ceramic plate having a first plurality of holes and a second plurality of holes respectively such that each of said first plurality of holes is aligned with a corresponding hole of said second plurality of holes, where each of said second plurality of holes is designed to have a diameter less than two Debye lengths of a plasma generated by said ICP source above said metal plate;
(e) flowing a gas A at a steady-state pressure to said ICP source for generating said plasma;
(f) grounding said metal plate to terminate said plasma;
(g) flowing into said chamber a gas B below said ceramic plate, whereby excited neutrals from said gas A, said gas B and said substrate react in a self-limiting manner to produce said conformal coating on said substrate; and
(h) doping said conformal coating by hydrogen by bombarding H+ ions onto said conformal coating under the influence of a potential difference caused by supplying negative voltage pulses to said platen while said gas A and said gas B have been switched off.

2. The method of claim 1 providing said conformal coating to be one of silicon dioxide (SiO2) and aluminum oxide (Al2O3).

3. The method of claim 2 wherein said doping causes said conformal coating to act as a leaky dielectric.

4. The method of claim 1 providing said conformal coating to be composed of more than one chemical species.

5. The method of claim 1 providing said lithography mask to be one of a binary photomask, a phase-shift photomask (PSM) and an extreme ultraviolet (EUV) mask.

6. The method of claim 1 providing said lithography mask to be one of a contact photomask, a proximity photomask and a projection photomask.

7. The method of claim 1 performing said protecting of said pattern on a reticle of said lithography mask when said lithography mask is an extreme ultraviolet (EUV) mask.

8. The method of claim 7, wherein said conformal coating is thin enough so as to cause no attenuation of incident EUV rays.

9. The method of claim 7, wherein said conformal coating is a sacrificial coating that is removed by plasma etching once said EUV mask has been manufactured.

10. The method of claim 1 providing the refractive indices of said conformal coating and an underlying substrate to be substantially similar.

11. The method of claim 1 further supplying positive voltage pulses to said platen while said gas A and said gas B have been switched off.

12. The method of claim 11 wherein the absolute value of said negative voltage pulses is greater than the value of said positive voltage pulses.

13. The method of claim 11 wherein the duration of each of said negative voltage pulses is greater than the duration of each of said positive voltage pulses.

14. The method of claim 1 wherein said platen is heated by a platen heater.

15. A conformal coating over a lithographic mask produced by a process comprising the steps of:
(a) using plasma enhanced atomic layer deposition (PEALD) for depositing said conformal coating on all sides and a distal end of a pattern existing on a substrate of said lithographic mask, said pattern meant for absorbing electromagnetic radiation incident on said lithography mask;
(b) retaining said conformal coating on said all sides and said distal end for protecting said pattern;
(c) said PEALD performed by placing said substrate atop a platen inside a chamber, said chamber further having a planar inductively coupled plasma (ICP) source laterally affixed at its distal end from said substrate;
(d) isolating said substrate from said ICP source in said chamber by a metal plate laterally affixed above said substrate and a ceramic plate laterally affixed below said metal plate but above said substrate, said metal plate and said ceramic plate having a first plurality of holes and a second plurality of holes respectively such that each of said first plurality of holes is aligned with a corresponding hole of said second plurality of holes, where each of said second plurality of holes is designed to have a diameter less than two Debye lengths of a plasma generated by said ICP source above said metal plate;
(e) flowing a gas A at a steady-state pressure to said ICP source for generating said plasma;
(f) grounding said metal plate to terminate said plasma;
(g) flowing into said chamber a gas B below said ceramic plate, whereby excited neutrals from said gas A, said gas B and said substrate react in a self-limiting manner to produce said conformal coating on said substrate; and
(h) doping said conformal coating by hydrogen by bombarding H+ ions onto said conformal coating under the influence of a potential difference caused by supplying negative voltage pulses to said platen while said gas A and said gas B have been switched off.

16. The conformal coating of claim 15, wherein said doping causes said conformal coating to act as a leaky dielectric.

17. The conformal coating of claim 15, wherein said lithographic mask is one of a binary photomask, a phase-shift photomask (PSM) and an extreme ultraviolet (EUV) mask.

18. The conformal coating of claim 15, wherein said process further comprises the step of supplying positive voltage pulses to said platen while said gas A and said gas B have been switched off.

19. The conformal coating of claim 18, wherein the absolute value of said negative voltage pulses is greater than the value of said positive voltage pulses.

20. The conformal coating of claim 18, wherein the duration of each of said negative voltage pulses is greater than the duration of each of said positive voltage pulses.
